(19) United States
(12) Patent Application Publication
(10) Pub. No.: US 2026/0129853 A1
(43) Pub. Date: May 7, 2026

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Byunggon PARK, Suwon-si (KR); Junbeom PARK, Suwon-si (KR); Yongjoon SHIN, Suwon-si (KR); Soo-Sik OH, Suwon-si (KR); Hyun Syek OH, Suwon-si (KR); Taesu YOON, Suwon-si (KR); Sooyoung LEE, Suwon-si (KR)

(73) Assignee: Samsung Electronics Co., Ltd., Suwon-si (KR)

(21) Appl. No.: 19/185,462

(22) Filed: Apr. 22, 2025

(30) Foreign Application Priority Data
Nov. 4, 2024 (KR) 10-2024-0154218

(51) Int. Cl. H10B 43/27; H01L 23/00; H01L 25/065; H01L 25/18; H10B 43/10; H10B 43/40; H10B 80/00

(52) U.S. Cl. CPC H10B 43/27; H10B 43/10; H10B 43/40; H10B 80/00; H10W 90/00; H10W 90/792

(57) ABSTRACT

The semiconductor device according to the present disclosure may include a peripheral circuit structure including a substrate having a first region and a second region and circuit elements on the substrate, the first region and the second region arranged in a first direction, and a cell structure on the peripheral circuit structure, the cell structure includes a mold structure including mold insulating layers and gate electrodes alternately stacked, a channel structure penetrating the mold structure in the first region, a contact structure in contact with the gate electrode in the second region, upper wires extending in a second direction intersecting the first direction, the upper wires spaced apart from each other in the first direction on the mold structure, and a marker pattern overlapping the upper wires in a third direction intersecting the first direction and the second direction.

### CROSS-REFERENCE TO RELATED APPLICATION

The present application claims priority to and the benefit of Korean Application No. 10-2024-0154218, filed on Nov. 4, 2024, in the Korean Intellectual Property Office, the entire disclosure of which is incorporated by reference herein.

### BACKGROUND

### Technical Field

The present disclosure relates to semiconductor devices and electronic systems including the same.

### Description of the Related Art

Semiconductor devices are key components used to control or amplify electrical signals of electronic devices, and various types of semiconductor devices can be manufactured. Semiconductor devices can be manufactured by forming various microstructures on a semiconductor wafer through several unit processes, such as an etching process, a deposition process, or an ion implantation process. In addition, it is desirable to check whether defects have occurred, the location of the defects, etc. after a semiconductor device has been manufactured.

In order to analyze defects in semiconductor devices, optical equipment such as electron microscopes may be used to observe the semiconductor devices. In particular, in order to quickly determine where a defect has occurred, etc., the location of the defect can be relatively determined based on some of a number of structures of a semiconductor device.

### SUMMARY

The present disclosure has been made in an effort to provide semiconductor devices including a marker pattern that facilitates the determination of the location of defects.

According to some example embodiments of the present disclosure to solve the above-mentioned technical problems, a semiconductor device includes a peripheral circuit structure including a substrate having a first region and a second region and circuit elements on the substrate, the first region and the second region arranged in a first direction, and a cell structure on the peripheral circuit structure. The cell structure includes a mold structure including mold insulating layers and gate electrodes alternately stacked, a channel structure penetrating the mold structure in the first region, a contact structure in contact with the gate electrode in the second region, upper wires extending in a second direction intersecting the first direction, and a marker pattern overlapping the upper wires in a third direction intersecting the first direction and the second direction.

According to some example embodiments of the present disclosure to solve the above-mentioned technical problems, a semiconductor device includes a peripheral circuit structure including comprising a substrate having a first region and a second region arranged side by side in a first direction, and circuit elements on the substrate, the first region and the second region in a first direction, and a cell structure on the peripheral circuit structure. The cell structure includes a mold structure including mold insulating layers and gate electrodes alternately stacked; a channel structure penetrating the mold structure in the first region; a contact structure in contact with the gate electrode in the second region; an upper wire comprising a cell upper wire in the first region and an extension upper wire in the second region, extending in a second direction intersecting the first direction; and a marker pattern including a cell marker pattern overlapping the cell upper wire in a third direction intersecting the first direction and the second direction and an extension marker pattern overlapping the extension upper wire. The extension marker pattern overlaps at least a portion of the cell marker pattern in the first direction.

According to some example embodiments of the present disclosure to solve the above-mentioned technical problems, an electronic system includes a main substrate, a semiconductor device including a peripheral circuit structure and a cell structure stacked on the peripheral circuit structure on the main substrate, and a controller electrically connected to the semiconductor device on the main substrate. The cell structure incudes a mold structure including a plurality of mold insulating layers and a plurality of gate electrodes alternately stacked, the plurality of mold insulating layers and the plurality of gate electrodes extending in a first direction, a channel structure penetrating the mold structure in a first region; a contact structure contacting the gate electrode in a second region; upper wires including a cell upper wire in the first region and an extension upper wire in the second region, extending in a second direction intersecting the first direction, and spaced apart from each other in the first direction; and a marker pattern including a cell marker pattern overlapping the cell upper wire in a third direction intersecting the first direction and the second direction and an extension marker pattern overlapping the extension upper wire. The extension marker pattern overlaps at least a portion of the cell marker pattern in the first direction.

According to some example embodiments of the present disclosure to solve the above-mentioned technical problems, a method of manufacturing includes forming, on a plate layer and first interlayer insulting film, a second layer insulating film, forming a via hole in the second layer insulating film, injecting a metal material into the via hole to form via structures, forming a metal layer on upper surfaces of the via structures and the second interlayer insulating film, placing a mask layer on an upper surface of the metal layer; etching the metal layer to form upper wires, each of the upper wires including a marker hole.

According to some example embodiments of the present disclosure to solve the above-mentioned technical problems, the method includes forming the marker hole such that a thickness of the upper wires are a same thickness as a thickness in the marker hole in a direction perpendicular to the upper surface of the second interlayer insulating film.

According to some example embodiments of the present disclosure, it may be possible to more quickly and more easily analyze defects occurring in semiconductor devices based on a marker pattern.

According to some example embodiments of the present disclosure, it may be possible to form a marker pattern on semiconductor devices without adding a separate manufacturing step.

### BRIEF DESCRIPTION OF THE DRAWINGS

FIG. 1 is a plan view of a semiconductor device according to some example embodiments of the present disclosure.

FIG. 2 illustrates a cross section taken along line X-X′ in FIG. 1.

FIG. 3 is an enlarged view of portion A in FIG. 1.

FIGS. 4 and 5 are enlarged views of portion B in FIG. 2.

FIG. 6 is a view for illustrating a marker pattern according to some example embodiments of the present disclosure.

FIGS. 7 to 10 are plan views of semiconductor devices including marker patterns according to some example embodiments of the present disclosure.

FIG. 11 is a plan view of a semiconductor device including a marker pattern according to some example embodiments of the present disclosure.

FIGS. 12 to 16 illustrate intermediate steps of a method for manufacturing a semiconductor device according to some example embodiments of the present disclosure.

FIG. 17 is a plan view of a semiconductor device including a marker pattern according to some example embodiments of the present disclosure.

FIGS. 18 to 22 are views of intermediate steps of a method of manufacturing a semiconductor device according to some example embodiments of the present disclosure.

FIG. 23 is a plan view of a semiconductor device including a marker pattern according to some example embodiments of the present disclosure.

FIG. 24 is an example block diagram for illustrating an electronic system according to some example embodiments of the present disclosure.

FIG. 25 is an example perspective view for illustrating an electronic system according to some example embodiments of the present disclosure.

FIG. 26 is a schematic view of a cross section taken along line V-V in FIG. 24.

### DETAILED DESCRIPTION

Hereinafter, with reference to the attached drawings, a semiconductor device according to some example embodiments of the present disclosure will be described in detail.

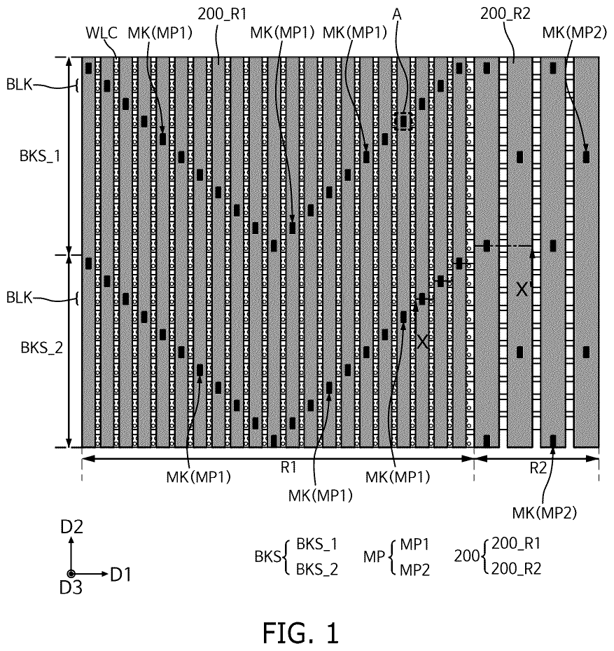

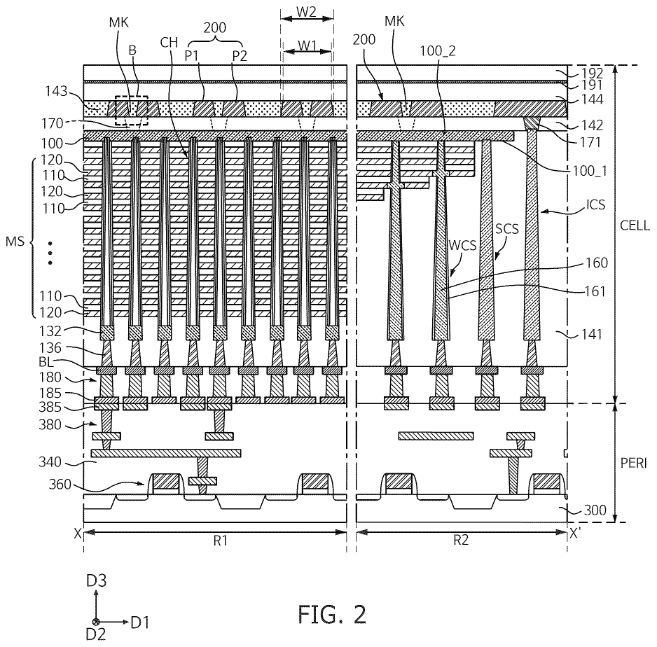

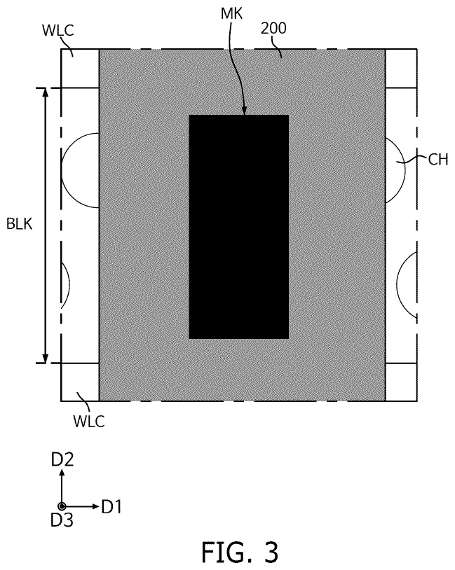

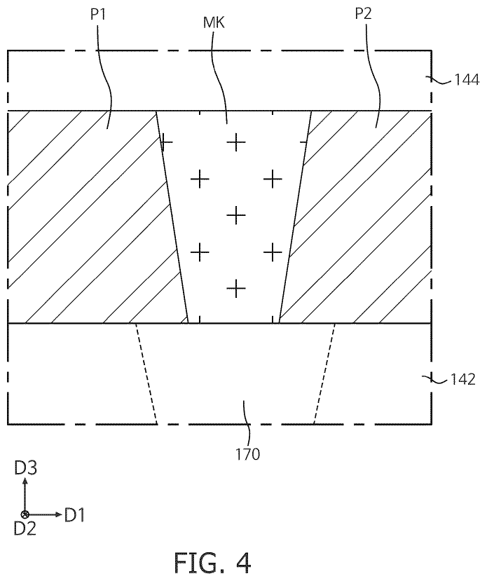

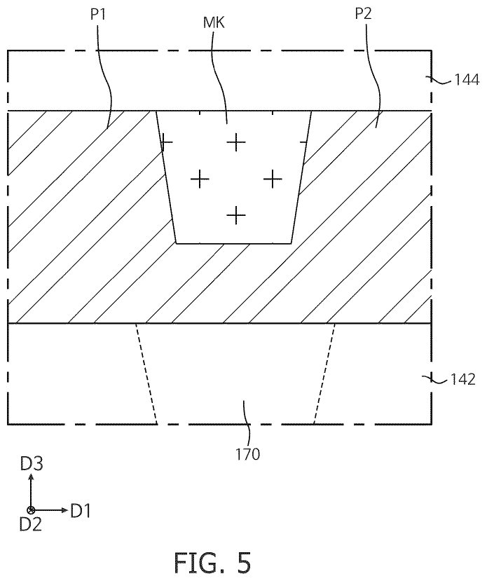

FIG. 1 is a plan view of a semiconductor device according to some example embodiments of the present disclosure. FIG. 2 illustrates a cross section taken along line X-X′ in FIG. 1. FIG. 3 is an enlarged view of portion A in FIG. 1. FIGS. 4 and 5 are enlarged views of portion B in FIG. 2.

Referring to FIGS. 1 and 2, the semiconductor device according to some example embodiments of the present disclosure may include a first region R1 and a second region R2.

The first region R1 may be a region where a memory cell array is arranged. The memory cell array may include a plurality of memory cell blocks BLK. Each of the memory cell blocks BLK may include a plurality of memory cells. Each of the memory cell blocks BLK may extend in a first direction D1. The plurality of memory cell blocks BLK may be separated from each other by word line cutting structures WLC.

The second region R2 may be an extended region and a penetration region. For example, a contact structure WCS, a source contact structure SCS, an input/output contact structure ICS, etc. may be arranged in the second region R2.

The first region R1 and the second region R2 may be disposed side by side in the first direction D1. However, the present disclosure is not limited thereto, and the second region R2 may surround the first region R1.

The memory cell blocks BLK may form a cell block structure BKS. For example, in FIG. 1, a first cell block structure BKS_1 and a second cell block structure BKS_2 have been illustrated. The drawing shows the first cell block structure BKS_1 and the second cell block structure BKS_2 each including 11 memory cell blocks BLK, but the present disclosure is not limited thereto. A marker pattern MP may be repeatedly formed in each of the first cell block structure BKS_1 and the second cell block structure BKS_2. That is, the marker pattern MP may be repeated identically (or substantially identically) in each of the first cell block structure BKS_1 and the second cell block structure BKS_2.

In a plan view, the word line cutting structures WLC may be connected to each other as one piece. In some example embodiments, the word line cutting structures WLC may be spaced apart from each other in the first direction D1.

Each of the word line cutting structures WLC may extend in a third direction D3 to cut a mold structure MS. The mold structure MS may be severed by the word line cutting structures WLC to form the plurality of memory cell blocks BLK. For example, one of the memory cell blocks BLK may be placed between two of the word line cutting structures WLC adjacent to each other. A plurality of channel structures CH may be placed within each of the memory cell blocks BLK defined by the word line cutting structures WLC.

The plurality of channel structures CH may be arranged in a zigzag shape. For example, the plurality of channel structures CH may be arranged alternately in the first direction D1 and a second direction D2. The plurality of channel structures CH arranged in a zigzag shape may improve the integration density of the semiconductor device. In some example embodiments of the present disclosure, the plurality of channel structures CH may be arranged in a honeycomb shape.

Referring to FIG. 2, a semiconductor device according to some example embodiments of the present disclosure may include a peripheral circuit structure PERI and a cell structure CELL disposed on the peripheral circuit structure PERI.

The peripheral circuit structure PERI may include a peripheral circuit board 300, circuit elements 360, an interlayer insulating film 340, a plurality of wiring structures 380, and first bonding metal layers 385.

The peripheral circuit board 300 may include a semiconductor substrate, such as a silicon substrate, a germanium substrate, or a silicon-germanium substrate. In other embodiments, the peripheral circuit board 300 may include a silicon-on-insulator (SOI) substrate, a germanium-on-insulator (GOI) substrate, etc.

The circuit elements 360 may be formed on the peripheral circuit board 300. The circuit elements 360 may form a peripheral circuit that controls the operation of the semiconductor device. For example, the surface of the peripheral circuit board 300 on which the circuit elements 360 are placed may be referred to as the front side of the peripheral circuit board 300. In contrast, the surface of the peripheral circuit board 300 opposite the front side thereof may be referred to as the back side of the peripheral circuit board 300.

The circuit elements 360 may include transistors, for example, but the present disclosure is not limited thereto. For example, the circuit elements 360 may include various active elements such as transistors, as well as various passive elements such as capacitors, resistors, and inductors.

The interlayer insulating film 340 may be placed on the front side of the peripheral circuit board 300. The plurality of wiring structures 380 may be arranged within the interlayer insulating film 340. The interlayer insulating film 340 may include an insulating material. For example, the interlayer insulating film 340 may include at least one of silicon oxide, silicon oxynitride, and a low-k material having a lower dielectric constant than that of silicon oxide, but the present disclosure is not limited thereto.

The plurality of wiring structures 380 may electrically connect the circuit elements 360 and bit lines BL. The plurality of wiring structures 380 may include a plurality of layers. The plurality of wiring structures 380 may contain a conductive material. The plurality of wiring structures 380 may contain, for example, tungsten (W) or copper (Cu), but the present disclosure is not limited thereto. In some example embodiments, the number of layers, the shape, etc. of the plurality of wiring structures 380 may be varied.

A semiconductor device according to some example embodiments may have a chip to chip (C2C) structure. To form the C2C structure, after an upper chip including the cell structure CELL has been fabricated on a first wafer and a lower chip including the peripheral circuit structure PERI has been fabricated on a second wafer other than the first wafer, the upper chip and the lower chip may be connected to each other by a bonding process.

The bonding process may mean a process of electrically connecting a second bonding metal layer 185 formed on the top metal layer of the upper chip, e.g., the top layer in the direction extending from a second surface 100_2 of a plate layer 100 to a first surface 100_1, and a first bonding metal layer 385 formed on the top metal layer of the lower chip. For example, when the first bonding metal layer 385 and the second bonding metal layer 185 are formed of copper (Cu), the bonding process may be a Cu—Cu bonding process. In some example embodiments, the first bonding metal layer 385 and the second bonding metal layer 185 may also be formed of aluminum (Al) or tungsten (W).

The cell structure CELL may include the plate layer 100, via structures 170 and 171, an upper wire 200, a gate electrode 120, the channel structures CH, the word line cutting structures WLC, the contact structure WCS, the source contact structures SCS, the input/output contact structures ICS, first to fourth interlayer insulating films 141 to 144, and the second bonding metal layer 185.

The plate layer 100 may include the first surface 100_1 and the second surface 100_2 that are opposite to each other. The first surface 100_1 may face the peripheral circuit structure PERI, and the second surface 100_2 may face the upper wire 200. In the third direction D3, the first surface 100_1 may be a lower surface, and the second surface 100_2 may be an upper surface.

The plate layer 100 may have an upper surface extending in the first direction D1 and the second direction D2. The plate layer 100 may serve as a common source line (CSL) of the semiconductor device. The plate layer 100 may contain a conductive material. For example, the plate layer 100 may contain a semiconductor material, such as a group IV semiconductor, a group III-V compound semiconductor, or a group II-VI compound semiconductor. For example, the group IV semiconductor may include silicon, germanium, or silicon-germanium. The plate layer 100 may further include impurities. The plate layer 100 may be provided as a polycrystalline semiconductor layer, such as a polycrystalline silicon layer, or an epitaxial layer.

Directions parallel to the first and second surfaces 100_1 and 100_2 of the plate layer 100 and intersecting with each other may be referred to as the first direction D1 and the second direction D2. A direction intersecting with the first direction D1 and the second direction D2 may be referred to as the third direction D3.

The cell structure CELL may include the first region R1 and the second region R2 arranged side by side in the first direction D1.

A memory cell array including a plurality of memory cells may be formed in the first region R1. For example, the channel structure CH, the gate electrode 120, the bit line BL, etc., which will be described below, may be arranged in the first region R1. The memory cell array may be placed on the first surface 100_1 of the plate layer 100.

The second region R2 may be around the first region R1. For example, the second region R2 may surround the first region R1 in a planar view. In the second region R2, the gate electrodes 120 to be described below may be stacked in a step shape. In the second region R2, the contact structure WCS and a dummy channel structure, which will be described below, may be positioned.

The mold structure MS may be placed on the first surface 100_1 of the plate layer 100. The mold structure MS may include a plurality of gate electrodes 120 and a plurality of mold insulating layers 110, which are stacked on the plate layer 100. Each of the gate electrodes 120 and each of the mold insulating layers 110 may have a layered structure extending parallel to the first surface 100_1 of the plate layer 100. The gate electrodes 120 may be sequentially stacked on the plate layer 100 while being spaced apart from each other by the mold insulating layers 110. In some example embodiments, the mold structure MS may be formed by stacking a plurality of mold structures. The gate electrode 120 may contain a conductive material, e.g., a metal such as tungsten (W), cobalt (Co), and/or nickel (Ni) and/or a semiconductor material such as silicon, but the present disclosure is not limited thereto. The mold insulating layers 110 may each contain an insulating material, for example, at least one of silicon oxide, silicon nitride, and silicon oxynitride, but the present disclosure is not limited thereto.

The mold structures MS may be vertically stacked and surround the channel structures CH. In some example embodiments, each of the channel structures CH may be surrounded by the plurality of mold structures. In this case, the channel structure CH may include multiple channel structures connected to each other.

The first interlayer insulating film 141 may be formed on the first surface 100_1 of the plate layer 100 to cover the mold structure MS. In some example embodiments, the first interlayer insulating film 141 may include multiple layers of interlayer insulating films that are sequentially stacked on the plate layer 100. The first interlayer insulating film 141 may contain, for example, at least one of silicon oxide, silicon oxynitride, and a low-k material having a lower dielectric constant than that of silicon oxide, but the present disclosure is not limited thereto.

The channel structure CH may extend in the third direction D3 perpendicular to the first surface 100_1 of the plate layer 100. The channel structure CH may penetrate the mold structure MS. For example, the channel structure CH may penetrate through and intersect with each of the plurality of gate electrodes 120. The channel structure CH may have the shape of a pillar, e.g., a cylindrical shape, extending in the third direction D3. In some example embodiments, the channel structure CH may have an inclined side surface such that the cross-sectional width thereof becomes narrower toward the plate layer 100, but the present disclosure is not limited thereto.

The width of a portion of the channel structure CH may decrease toward the first surface 100_1 of the plate layer 100. In some example embodiments, when the channel structure CH is formed by connecting a plurality of channel structures, it may have a bend. This may be a profile resulting from an etching process for forming the channel structure CH.

The channel structure CH may include a filling insulating layer, a semiconductor pattern, and an information storage film.

The semiconductor pattern may extend in the third direction D3 and penetrate the mold structure MS. Only a cup-shaped semiconductor pattern has been illustrated, but the present disclosure is not limited thereto. The semiconductor pattern may have various shapes, such as a cylindrical shape, the shape of a rectangular cylinder, and the shape of a solid pillar. The semiconductor pattern may include a semiconductor material, such as single crystal silicon, polycrystalline silicon, an organic semiconductor material, and/or a carbon nanostructure, but the present disclosure is not limited thereto.

The information storage film may be interposed between the semiconductor pattern and each of the gate electrodes 120. For example, the information storage film may extend along the outer surface of the semiconductor pattern. The information storage film may contain, for example, at least one of silicon oxide, silicon nitride, silicon oxynitride, and a high-k material having a higher dielectric constant than that of silicon oxide. The high-k material may include, for example, at least one of aluminum oxide, hafnium oxide, lanthanum oxide, tantalum oxide, titanium oxide, lanthanum hafnium oxide, lanthanum aluminum oxide, dysprosium scandium oxide, and combinations thereof. In some example embodiments, the information storage film may include multiple films. The information storage film may include a tunnel insulating film, a charge storage film, and a blocking insulating film, which are sequentially stacked on the outer surface of the semiconductor pattern.

The tunnel insulating film may contain, for example, silicon oxide or a high-k material having a higher dielectric constant than that of silicon oxide, e.g., aluminum oxide (Al₂O₃) and hafnium oxide (HfO₂). The charge storage film may contain, for example, silicon nitride. The blocking insulating film may contain, for example, silicon oxide or a high-k material having a higher dielectric constant than that of silicon oxide, e.g., aluminum oxide (Al₂O₃) and hafnium oxide (HfO₂).

In some example embodiments, a channel pad 132 may be positioned on the channel structure CH. The channel pad 132 may be formed to be connected to the semiconductor pattern. For example, the channel pad 132 may be placed within the first interlayer insulating film 141 and connected to one end of the semiconductor pattern. The channel pad 132 may contain, for example, polysilicon doped with impurities, but the present disclosure is not limited thereto.

The bit line BL may be formed above the mold structure MS and the first interlayer insulating film 141. The bit line BL may extend in the second direction D2 and intersect with the word line cutting structures WLC. In addition, the bit line BL may extend in the second direction D2 and be connected to the plurality of channel structures CH arranged in the first direction D1. For example, a bit line contact 136 may be formed within the first interlayer insulating film 141 to be connected to the upper portions of each of the channel structures CH. The bit line BL may be electrically connected to the channel structure CH through the bit line contact 136.

The contact structures WCS may be placed on the plate layer 100. The contact structures WCS may extend in the third direction D3 and penetrate the first interlayer insulating film 141 and the mold structure MS. The contact structures WCS may extend in the direction in which the components of the mold structure MS are stacked. The contact structures WCS may penetrate at least a portion of the mold structure MS in the second region R2.

The width of a portion of the contact structures WCS may decrease toward the first surface 100_1 of the plate layer 100. The width of the contact structures WCS may decrease toward the first surface 100_1 of the plate layer 100 within the mold structure MS. This may be a profile resulting from an etching process for forming the contact structure WCS.

Each of the contact structures WCS may be electrically connected to each of the gate electrodes 120 in the second region R2. Each of the contact structures WCS may be electrically connected to one of the gate electrodes 120.

The contact structures WCS may include a first spacer film 161 and a first filling film 160. The first filling film 160 may penetrate the first interlayer insulating film 141 and the mold structure MS. The first spacer film 161 may extend along the side surface and the upper surface in the third direction D3 of the first filling film 160. The first spacer film 161 may not be placed between the first filling film 160 and the gate electrode 120 electrically connected thereto among the plurality of gate electrodes 120. For example, the first spacer film 161 may contain an insulating material, and the first filling film 160 may contain a conductive material.

In some example embodiments, a sidewall of the contact structure WCS in contact with the gate electrode 120 may protrude. The thickness of a sidewall of the gate electrode 120 in contact with the contact structure WCS may be greater than the thickness of a sidewall of the gate electrode not in contact with the contact structure WCS, but the present disclosure is not limited thereto.

The contact structures WCS may be electrically connected to the bit line BL. The contact structures WCS may be electrically connected to the bit line BL through a contact wiring. The contact wiring may contain a conductive material. For example, the contact wiring may contain tungsten (W) or copper (Cu), but the present disclosure is not limited thereto.

The source contact structures SCS may be placed in the second region R2. The source contact structures SCS may penetrate at least a portion of the first interlayer insulating film 141 and the plate layer 100 in the second region R2. The source contact structures SCS may not penetrate the gate electrode 120. The source contact structures SCS may penetrate at least a portion of the plate layer 100 and be electrically connected to the plate layer 100. In some example embodiments, the source contact structures SCS may not be directly connected to the peripheral circuit structure PERI, but the present disclosure is not limited thereto.

The input/output contact structure ICS may be arranged in the second region R2. In some example embodiments, a plurality of input/output contact structures ICS may be provided. The input/output contact structure ICS may not penetrate the gate electrode 120. The input/output contact structure ICS may electrically connect the circuit elements 360 of the peripheral circuit structure PERI and a second via structure 171. The input/output contact structure ICS may electrically connect the circuit elements 360 of the peripheral circuit structure PERI and the upper wire 200.

The input/output contact structures ICS may extend in the third direction D3 and penetrate the first interlayer insulating film 141 to be electrically connected to the second via structure 171. The width of a portion of the input/output contact structures ICS may decrease toward the first surface 100_1 of the plate layer 100.

The via structures 170 and 171 may extend in the second direction D2 on the second surface 100_2 of the plate layer 100 and be spaced apart from each other in the first direction D1.

The via structures 170 and 171 may be disposed in the first region R1 and the second region R2, respectively. The via structures 170 and 171 may be spaced apart from each other in the first direction D1 and the second direction D2. The first via structures 170 may be arranged in the first region R1, and the second via structures 171 may be arranged in the second region R2. In some example embodiments, some of the second via structures 171 may be connected to the input/output contact structure ICS.

In the second direction D2, a marker MK may be arranged at a position other than the positions of the first and second via structures 170 and 171. The marker MK and the first and second via structures 170 and 171 may not overlap in the third direction D3. For example, the marker MK may not be arranged on the upper surface of the via structure 170 and 171. In some example embodiments, the marker MK may be arranged to overlap the via structure 170 and 171 in the third direction D3, or may be arranged to overlap each of the via structure 170 and 171 and a second interlayer insulating film 142 in the third direction D3.

A distance between the first via structures 170 and a distance between the second via structures 171 may be different from each other. In some example embodiments, the length of each of the first via structures 170 in the first direction D1 and the length of each of the second via structures 171 in the first direction D1 may be different from each other.

In the first direction D1 and the second direction D2, the width of the lower surface of each of the via structures 170 and 171 facing the second surface 100_2 of the plate layer 100 may be smaller than or equal to the width of the upper surface of each of the via structures 170 and 171. For example, the width of each of the via structures 170 and 171 may become smaller toward the plate layer 100 in the third direction D3.

The second interlayer insulating film 142 may be placed at the same or about the same level as the via structures 170 and 171. The second interlayer insulating film 142 may be positioned between the via structures 170 and 171. The second interlayer insulating film 142 may be arranged on the side surfaces of the via structures 170 and 171.

The upper wire 200 may be arranged on the upper surfaces of the via structures 170 and 171. For example, power may be supplied to the semiconductor device through the upper wire 200. A plurality of upper wires 200 may be provided. Each of the plurality of upper wires 200 may extend in the second direction D2 and be spaced apart from each other in the first direction D1. For example, the via structures 170 and 171 and the upper wire 200 may contain tungsten (W), aluminum (Al), copper (Cu), tungsten nitride (WN), tantalum nitride (TaN), titanium nitride (TiN), or a combination thereof.

The upper wire 200 may include a cell upper wire 200_R1 in the first region R1 and an extension upper wire 200_R2 in the second region R2. The width of the cell upper wire 200_R1 in the first direction D1 may be smaller than the width of the extension upper wire 200_R2 in the first direction D1.

A third interlayer insulating film 143 may be placed at a higher level than the via structures 170 and 171. The third interlayer insulating film 143 may be disposed on a side surface of the upper wire 200. The third interlayer insulating film 143 may be arranged between the upper wires 200 adjacent to each other in the first direction D1. The third interlayer insulating film 143 may extend in the second direction D2 and be spaced apart from each other in the first direction D1.

In the first direction D1 and the second direction D2, a width W2 of the lower surface of each of the upper wires 200 may be equal to or larger than a width W1 of the upper surface of each of the upper wires 200. In other words, the width of each of the upper wires 200 may increase toward the plate layer 100 in the third direction D3.

The marker pattern MP may include a plurality of markers MK. The marker pattern MP may overlap the upper wire 200 in the third direction D3. Each of the plurality of markers MK may overlap each of the plurality of upper wires 200 in the third direction D3.

Each of the plurality of markers MK may divide the upper wire 200 into a first portion P1 and a second portion P2. That is, the marker MK may be placed between the first portion P1 and the second portion P2 of the upper wire 200.

The marker pattern MP according to the present disclosure may be placed on the upper wire 200. The marker pattern MP may overlap the upper wire 200 in the first direction D1 and the second direction D2.

The fourth interlayer insulating film 144 may be placed on the plurality of markers MK and upper wires 200. The fourth interlayer insulating film 144 may be positioned on the upper surface of the plurality of markers MK and upper wires 200.

The marker pattern MP and the first to fourth interlayer insulating films 141 to 144 may each contain an insulating material. For example, the marker pattern MP and the first to fourth interlayer insulating films 141 to 144 may respectively contain at least one of silicon oxide, silicon nitride, and silicon carbide. In some example embodiments, the first to fourth interlayer insulating films 141 to 144 may each include multiple insulating layers.

A passivation layer 191 and 192 may be placed on the upper surface of the fourth interlayer insulating film 144. The passivation layer 191 and 192 may serve as a layer that protects the semiconductor device. In some example embodiments, the fourth interlayer insulating film 144 and the passivation layer 191 and 192 may have openings that expose at least a portion of the upper wires 200.

A first passivation layer 191 and a second passivation layer 192 may be sequentially stacked on the fourth interlayer insulating film 144. The first passivation layer 191 may contain silicon nitride (SiN), and the second passivation layer 192 may contain a photosensitive insulating film. For example, the second passivation layer 192 may contain a polyimide-based material such as photosensitive polyimide (PSPI).

Referring to FIG. 3, the marker MK may be placed on the upper wire 200. From a planar viewpoint, the marker MK may be positioned in the center of the width of the first direction D1 of the upper wire 200. In some example embodiments, the marker MK may be arranged closer to one side of the upper wire 200.

The marker MK may be arranged to overlap the cell block BLK in a third direction D3. The marker MK may be arranged to not overlap the word line cutting structure WLC in the third direction D3. In this case, the marker MK may indicate the address of the cell block BLK. The position of the cell block BLK may be determined based on the position of the marker MK in a first direction D1 and a second direction D2. In some example embodiments, the marker MK may overlap the word line cutting structure WLC in the third direction D3.

From a planar viewpoint, the marker MK may have a rectangular shape. The length of the marker MK in the first direction D1 may be shorter than the length thereof in the second direction D2. That is, the marker MK may have a rectangular shape that is longer in the second direction D2 than in the first direction D1. However, the present disclosure is not limited thereto, and the marker MK may have various shapes. In some example embodiments, the marker MK may have a rectangular shape that is longer in the first direction D1 than in the second direction D2, or may have a square shape.

Referring to FIGS. 4 and 5, the marker MK according to the present disclosure may overlap the upper wire 200 in a first direction D1 and a second direction D2. The marker MK may penetrate at least a portion of the upper wire 200 in a third direction D3. The upper surface of the marker MK may be located at the same or about the same level as the upper surface of the upper wire 200.

Referring to FIG. 4, the marker MK according to the present disclosure may divide the upper wire 200 into the first portion P1 and the second portion P2. The marker MK may penetrate the upper wire 200 in the third direction D3. That is, the marker MK may be placed between the first portion P1 and the second portion P2 of the upper wire 200. The lower surface of the marker MK may be positioned at the same or about the same level as the lower surface of the upper wire 200. The lower surface of the marker MK may be in contact with the upper surface of the second interlayer insulating film 142. In some example embodiments, the lower surface of the marker MK may also be in contact with the upper surface of the via structure 170 and 171.

Referring to FIG. 5, the lower surface of the marker MK according to the present disclosure may be positioned at a level higher than the lower surface of the upper wire 200. The marker MK may penetrate a portion of the upper wire 200 in a third direction D3. The upper wire 200 may be arranged on the side surfaces and the lower surface of the marker MK. The lower surface of the marker MK may be spaced apart from the upper surface of the second interlayer insulating film 142 in the third direction D3. In some example embodiments, the lower surface of the marker MK may be spaced apart from the upper surface of the via structure 170 and 171 in the third direction D3.

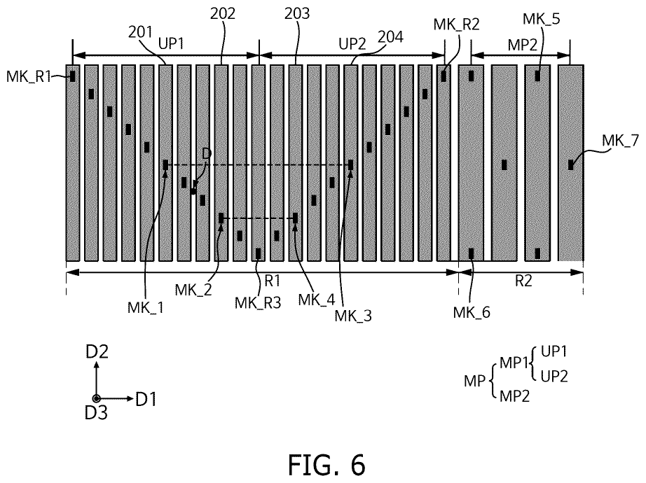

FIG. 6 is a view for illustrating a marker pattern according to some example embodiments of the present disclosure.

Referring to FIG. 6, the marker pattern MP may include a first marker pattern MP1 and a second marker pattern MP2. The first marker pattern MP1 may be arranged in a first region R1, and the second marker pattern MP2 may be placed in a second region R2. The first marker pattern MP1 may be referred to as a “cell marker pattern,” and the second marker pattern MP2 may be referred to as an “extension marker pattern.” The first marker pattern MP1 may be arranged to overlap the cell upper wire 200_R1 (see FIG. 1) in a third direction D3, and the second marker pattern MP2 may be disposed to overlap the extension upper wire 200_R2 (see FIG. 1) in the third direction D3.

The marker pattern MP may be repeated in a first direction D1 and a second direction D2. That is, the marker pattern MP may be identically (or substantially identically) arranged in each of a plurality of cell block structures BKS_1 and BKS_2, which are different from each other.

The upper wire may include a first upper wire 201, a second upper wire 202, a third upper wire 203, and a fourth upper wire 204. The second upper wire 202 may be spaced apart from the first upper wire 201 in the first direction D1. The fourth upper wire 204 may be spaced apart from the third upper wire 203 in the first direction D1.

A first marker MK_1 may be placed on the first upper wire 201, and a second marker MK_2 may be placed on the second upper wire 202. The first marker MK_1 and the second marker MK_2 may be positioned alternately in the first direction D1. The second marker MK_2 may be spaced apart from the first marker MK_1 in the first direction D1 and the second direction D2.

A third marker MK_3 may be arranged on the third upper wire 203, and a fourth marker MK_4 may be arranged on the fourth upper wire 204. The third marker MK_3 and the fourth marker MK_4 may be positioned alternately in the first direction D1. The fourth marker MK_4 may be spaced apart from the third marker MK_3 in the first direction D1 and the second direction D2.

The first marker pattern MP1 may include a first unit pattern UP1 and a second unit pattern UP2. Each of the first unit pattern UP1 and the second unit pattern UP2 may include 11 markers. The first unit pattern UP1 and the second unit pattern UP2 may share one marker.

The first unit pattern UP1 may include the first marker MK_1 and the second marker MK_2. That is, the first unit pattern UP1 may extend in a predetermined (or, alternatively, desired or selected) direction between the first direction D1 and the second direction D2. From a planar viewpoint, the first unit pattern UP1 may be inclined in the second direction D2 as it extends in the first direction D1. The second unit pattern UP2 may include the third marker MK_3 and the fourth marker MK_4. That is, the second unit pattern UP2 may extend in a predetermined (or, alternatively, desired or selected) direction between the first direction D1 and the second direction D2. From a planar viewpoint, the second unit pattern UP2 may be inclined in the second direction D2 as it extends in the first direction D1.

The first unit pattern UP1 and the second unit pattern UP2 may be symmetrical. The first unit pattern UP1 and the second unit pattern UP2 may be symmetrical to each other based on a line passing through, in the second direction D2, the point where the first unit pattern UP1 and the second unit pattern UP2 are connected to each other. For example, from a planar viewpoint, the first unit pattern UP1 and the second unit pattern UP2, which are connected to each other, may have the shape of a wedge protruding downward or a convex shape.

The first marker pattern MP1 may include a first reference marker MK_R1, a second reference marker MK_R2, and a third reference marker MK_R3. The first reference marker MK_R1 and the second reference marker MK_R2 may be placed at the uppermost end, e.g., the uppermost side in the second direction D2, of the first marker pattern MP1. The third reference marker MK_R3 may be placed at the lowest end, e.g., the lowest side in the second direction D2, of the first marker pattern MP1.

The first reference marker MK_R1 may be positioned furthest from a second region R2 among a plurality of markers of the first marker pattern MP1. The second reference marker MK_R2 may be positioned closest to the second region R2 among the plurality of markers of the first marker pattern MP1. The third reference marker MK_R3 may be positioned midway between the first reference marker MK_R1 and the second reference marker MK_R2 in the first direction D1. The first unit pattern UP1 and the second unit pattern UP2 may share the third reference marker MK_R3.

Nine markers may be placed between the first reference marker MK_R1 and the third reference marker MK_R3. That is, all the 11 markers of the first unit pattern UP1 may be spaced apart from each other by the same or about the same distance. The markers of the first unit pattern UP1 may be spaced apart from each other by the same or about the same distance in the first direction D1 and the second direction D2.

Nine markers may be placed between the second reference marker MK_R2 and the third reference marker MK_R3. That is, all the 11 markers of the second unit pattern UP2 may be spaced apart from each other by the same or about the same distance. The markers of the second unit pattern UP2 may be spaced apart from each other by the same or about the same distance in the first direction D1 and the second direction D2.

The first marker MK_1 may be located at the center of the first unit pattern UP1 in the second direction D2. The third marker MK_3 may be positioned at the center of the second unit pattern UP2 in the second direction D2. The first marker MK_1 may be placed midway between the first reference marker MK_R1 and the third reference marker MK_R3 in the first direction D1 and the second direction D2. The second marker MK_2 may be positioned midway between the second reference marker MK_R2 and the third reference marker MK_R3 in the first direction D1 and the second direction D2.

The second marker pattern MP2 may overlap at least a portion of the first unit pattern UP1 or the second unit pattern UP2 in the first direction D1. That is, the extension marker pattern may overlap at least a portion of the cell marker pattern in the first direction D1.

The second marker pattern MP2 may include a fifth marker MK_5, a sixth marker MK_6, and a seventh marker MK_7. The fifth marker MK_5, the sixth marker MK_6, and the seventh marker MK_7 may be referred to as a first extension marker EMK_1, a second extension marker EMK_2, and a third extension marker EMK_3, respectively.

The fifth marker MK_5 may overlap the first reference marker MK_R1 and the second reference marker MK_R2 in the first direction D1. The sixth marker MK_6 may overlap the third reference marker MK_R3 in the first direction D1. The seventh marker MK_7 may overlap the first marker MK_1 and the third marker MK_3 in the first direction D1. That is, the distance in the second direction D2 between the fifth marker MK_5 and the seventh marker MK_7 may be half the distance in the second direction D2 between the first reference marker MK_R1 and the third reference marker MK_R3. Similarly, the distance in the second direction D2 between the sixth marker MK_6 and the seventh marker MK_7 may be half the distance in the second direction D2 between the first reference marker MK_R1 and the third reference marker MK_R3.

The position of the second marker pattern MP2 may be determined based on the markers of the first marker pattern MP1. The markers of the second marker pattern MP2 may be arranged with a distance therebetween longer than the distance between the markers of the first marker pattern MP1.

Hereinafter, a method of determining the location of a defect D in the semiconductor device according to the present disclosure using the marker pattern MP will be described. The location of the defect D may be determined based on the first reference marker MK_R1 and the third reference marker MK_R3. First, the number of the plurality of markers arranged between the third reference marker MK_R3 and the first reference marker MK_R1 on the first unit pattern UP1 may be counted. It is seen that the defect D is between the fourth and fifth markers on a straight line from the third reference marker MK_R3 to the first reference marker MK_R1. As such, the location of the defect D may be more easily determined based on the regular structure of the marker pattern MP.

Hereinafter, marker patterns according to some example embodiments of the present disclosure will be described. Components identical to those disclosed in the above-described embodiments will be given the same reference numerals as those disclosed above, and a detailed description thereof may not be provided.

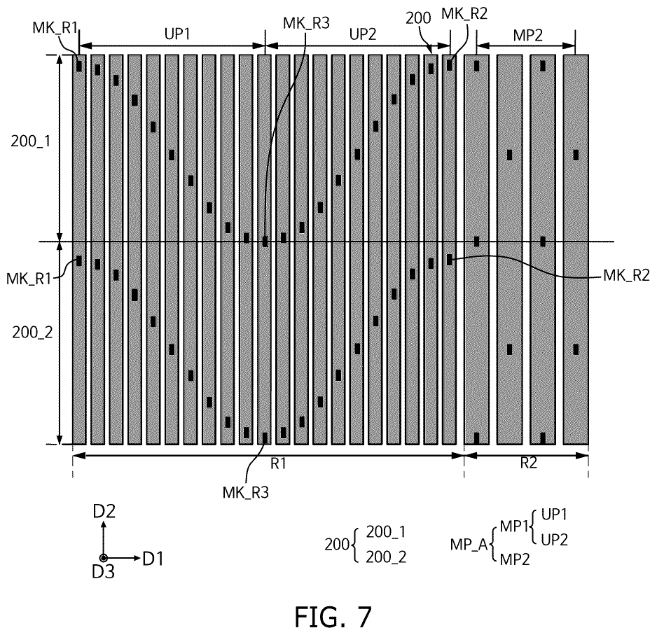

FIGS. 7 to 10 are plan views of semiconductor devices including marker patterns according to some example embodiments of the present disclosure.

Referring to FIGS. 7 to 10, the plurality of upper wires 200 may include a first section 200_1 corresponding to the first cell block structure BKS_1 (see FIG. 1) and a second section 200_2 corresponding to the second cell block structure BKS_2 (see FIG. 1).

A marker pattern may be formed in each of the first section 200_1 and the second section 200_2. The first section 200_1 and the second section 200_2 may be in contact with each other in a second direction D2. The first section 200_1 and the second section 200_2 may be separated by a straight line extending in a first direction D1.

Referring to FIG. 7, from a planar viewpoint, a marker pattern MP_A according to some example embodiments of the present disclosure may have the shape of a wave. In other words, the marker pattern MP_A may have a shape in which rises and falls are regularly repeated. That is, the marker pattern MP_A may have a shape in which upwardly convex sections and downwardly convex sections are repeated. As such, the marker pattern MP_A may correspond to a curve on which gradual rises and falls are repeated. The marker pattern MP_A may be formed in each of the first section 200_1 and the second section 200_2.

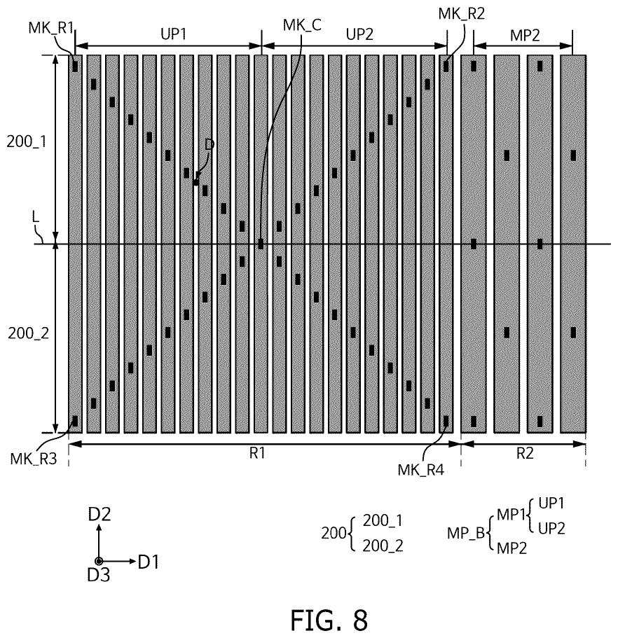

Referring to FIG. 8, a marker pattern MP_B according to the present disclosure may be symmetrical with respect to a reference line L, which is a straight line passing through a center reference marker MK_C and extending in the first direction D1. In addition, the marker pattern MP_B may be symmetrical with respect to a straight line passing through the center reference marker MK_C and extending in the second direction D2.

In the first section 200_1, a first unit pattern UP1 and a second unit pattern UP2 may be formed, and, in the second section 200_1, a pattern may be formed in the form of the first unit pattern UP1 and the second unit pattern UP2 that are symmetrically moved with respect to the reference line L. The marker pattern MP_B may be in the shape of a wedge protruding downward in the first section 200_1 and in the shape of a wedge protruding upward in the second section 200_2.

The marker pattern MP_B may include a first reference marker MK_R1, a second reference marker MK_R2, a third reference marker MK_R3, a fourth reference marker MK_R4, and the center reference marker MK_C.

The first reference marker MK_R1 may be located farthest from a second region R2 in the first section 200_1. The second reference marker MK_R2 may be placed closest to the second region R2. The third reference marker MK_R3 may be positioned farthest from the second region R2 in the second section 200_2. The fourth reference marker MK_R4 may be arranged closest to the second region R2 in the second section 200_2.

The first reference marker MK_R1 and the second reference marker MK_R2 may overlap each other in the first direction D1. The third reference marker MK_R3 and the fourth reference marker MK_R4 may overlap each other in the first direction D1. The first reference marker MK_R1 and the third reference marker MK_R3 may overlap each other in the second direction D2. The second reference marker MK_R2 and the fourth reference marker MK_R4 may overlap each other in the second direction D2.

The center reference marker MK_C may be shared by the first unit pattern UP1 and the second unit pattern UP2. That is, the center reference marker MK_C may be formed at the point where the first unit pattern UP1 and the second unit pattern UP2 overlap each other. The center reference marker MK_C may be on the reference line C. The center reference marker MK_C may be in the middle of the first reference marker MK_R1, the second reference marker MK_R2, the third reference marker MK_R3, and the fourth reference marker MK_R4.

The location of a defect D may be determined by referring to the marker pattern MP_B according to the present disclosure. The location of markers adjacent to the defect among markers placed in a straight line from the center reference marker MK_C may be determined. For example, in order to determine the location of the defect D, the number of multiple markers arranged between the center reference marker MK_C and the first reference marker MK_R1 may be counted. It is seen that the defect D is between the third and fourth markers on a straight line from the center reference marker MK_C to the first reference marker MK_R1.

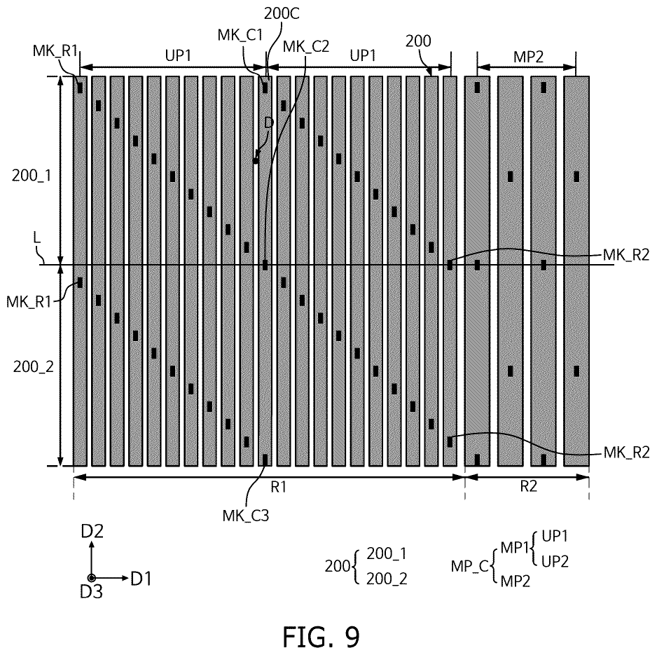

Referring to FIG. 9, a marker pattern MP_C according to some example embodiments of the present disclosure may have the first unit pattern UP1 repeated in the first direction D1 or the second direction D2. The first unit patterns UP1 may be spaced apart from each other in the second direction D2.

The marker pattern MP_C may have the first unit pattern UP1 repeated in the first direction D1 or the second direction D2, so that multiple markers may be formed on several upper wires 200. For example, a first center marker MK_C1, a second center marker MK_C2, and a third center marker MK_C3 may be formed on a center upper wire 200C. The first center marker MK_C1, the second center marker MK_C2, and the third center marker MK_C3 may overlap each other in the second direction D2. The second center marker MK_C2 may be placed on the reference line L.

The location of a defect D may be determined by referring to the marker pattern MP_C according to the present disclosure. Based on the center upper wire 200C, a marker adjacent to the defect D may be found. Because the marker pattern MP_C may be arranged at a predetermined (or, alternatively, desired or selected) location with a predetermined (or, alternatively, desired or selected) gap and have a regular structure, it may be possible to determine the location of the center upper wire 200C in advance. For example, the center upper wire 200C may be the 10th upper wire from an upper wire where a first reference marker MK_R1 is formed. It is seen that the defect D is, in the first direction D1, between the 9th and 10th upper wires from the upper wire where the first reference marker MK_R1 is formed. In addition, it is seen that the position in the second direction D2 of the defect D is similar to the position in the second direction D2 of the fourth marker on a straight line from the first reference marker MK_R1 to the second center marker MK_C2. As such, it may be possible to more easily determine the location of the defect D based on the marker pattern MP_C according to the present disclosure.

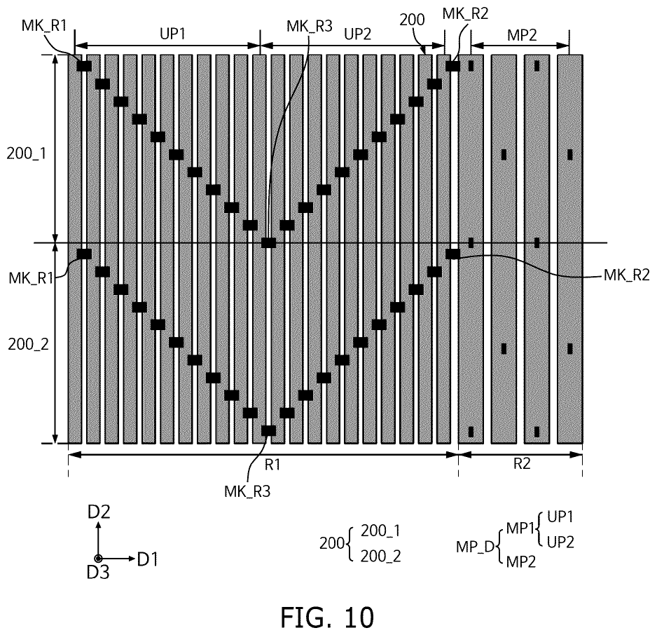

Referring to FIG. 10, a marker pattern MP_D according to some example embodiments of the present disclosure may overlap each of upper wires adjacent to each other among the plurality of upper wires 200 in the second direction D2. Specifically, the first marker pattern MP1 may overlap each of upper wires adjacent to each other among the plurality of upper wires 200 in the second direction D2. In some example embodiments, a portion of the marker pattern may be located within the upper wires from a planar viewpoint, while the remaining portion thereof may span over the upper wires adjacent to each other.

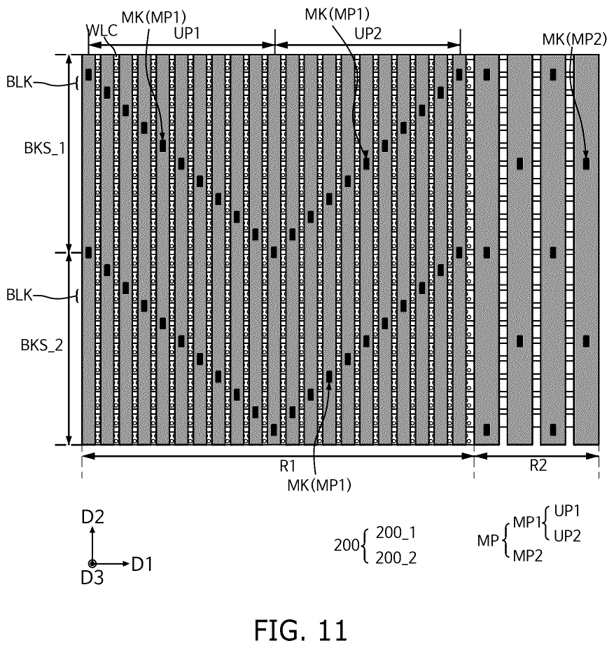

FIG. 11 is a plan view of the semiconductor device including the marker pattern according to some example embodiments of the present disclosure.

Referring to FIG. 11, the semiconductor device according to some example embodiments of the present disclosure may include the plurality of word line cutting structures WLC that separate the plurality of cell blocks BLK. The plurality of word line cutting structures WLC may extend in a first direction D1. The plurality of word line cutting structures WLC may be spaced apart from each other in a second direction D2.

The marker pattern MP may overlap the plurality of word line cutting structures WLC in a third direction D3. Each of the first marker pattern MP1 and the second marker pattern MP2 may overlap the plurality of word line cutting structures WLC in the third direction D3. That is, from a planar viewpoint, the marker pattern MP and the plurality of word line cutting structures WLC may intersect. In some example embodiments, some markers of the marker pattern MP may overlap the plurality of word line cutting structures WLC in the third direction D3, and the other markers thereof may overlap the plurality of cell blocks BLK in the third direction D3.

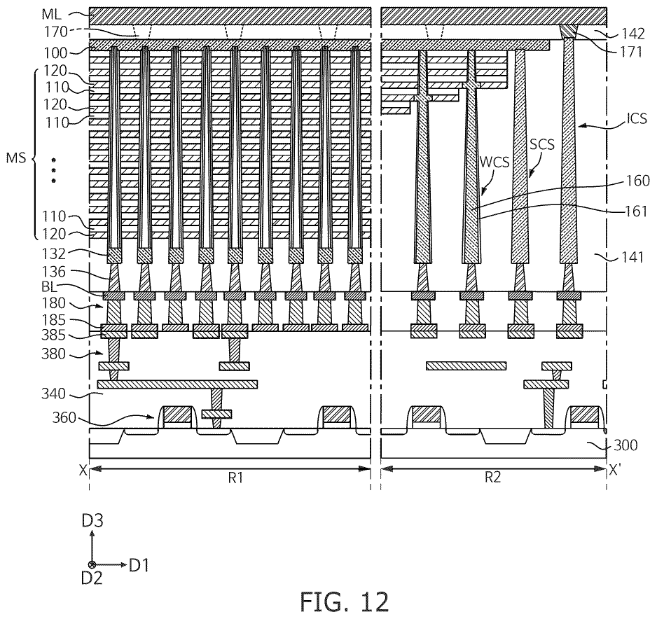

FIGS. 12 to 16 illustrate intermediate steps of a method for manufacturing a semiconductor device according to some example embodiments of the present disclosure. FIGS. 12 to 16 are views corresponding to a cross section taken along line X-X′ in FIG. 1.

Referring to FIG. 12, the second interlayer insulating film 142 may be formed on the plate layer 100 and the first interlayer insulating film 141. A via hole may be formed in the second interlayer insulating film 142 through an etching process. A metal material may be injected onto the upper surfaces of the via hole and the second interlayer insulating film 142. Thereafter, a planarization process may be performed on the upper surfaces of the via structure 170 and 171 and the second interlayer insulating film 142. For example, the planarization process may be a chemical mechanical polishing (CMP) process.

A metal layer ML may be formed on the upper surfaces of the via structure 170 and 171 and the second interlayer insulating film 142. For example, the metal layer ML may contain tungsten (W), aluminum (Al), copper (Cu), tungsten nitride (WN), tantalum nitride (TaN), titanium nitride (TiN), or a combination thereof.

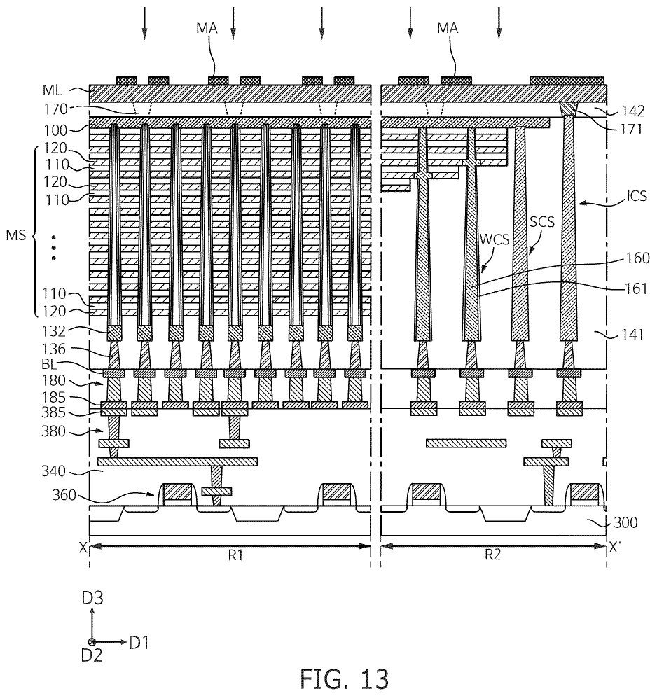

Referring to FIG. 13, a mask layer MA may be placed on the upper surface of the metal layer ML. An etching process may be carried out using the mask layer MA as an etching mask. A portion of the metal layer ML on which the mask layer MA is not disposed may be selectively removed through the etching process.

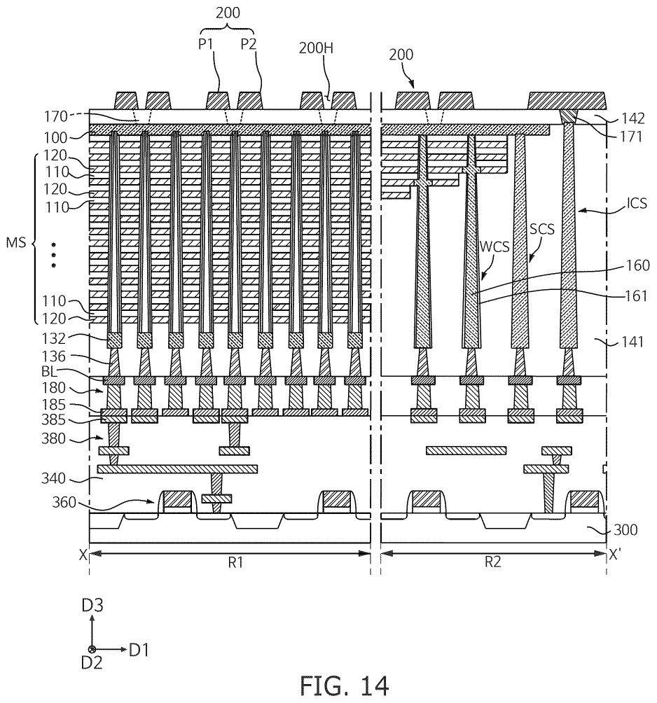

Referring to FIG. 14, the metal layer may be separated into the plurality of upper wires 200. In addition, a marker hole 200H may be formed in each upper wire 200. The marker hole 200H may separate the upper wire 200 into a first portion P1 and a second portion P2. That is, the depth of the marker hole 200H may be equal to the thickness of the metal layer ML. In some example embodiments, the marker hole 200H may penetrate at least one of the upper surface of the second interlayer insulating film 142 and the upper surface of the via structure 170 and 171. In this case, the depth of the marker hole 200H may be greater than the thickness of the metal layer ML. In some example embodiments, the distance between the upper surfaces of each of the upper wires 200 may be equal to the length in the first direction D1 of the upper surface of the marker hole 200H.

The cross-sectional area of the marker hole 200H may become smaller toward the upper surface of the second interlayer insulating film 142. The width of the upper surface of the marker hole 200H in the first direction D1 may be larger than the width of the lower surface of the marker hole 200H in the first direction D1. The shape of the marker hole 200H may have a profile formed by an etching process.

The step of forming the marker hole 200H may be performed together with the process of separating the metal layer into the plurality of upper wires 200. That is, a separate process may not be added to form the marker hole 200H. Accordingly, it may be possible to prevent or reduce an increase in process time, etc., for forming the marker hole 200H.

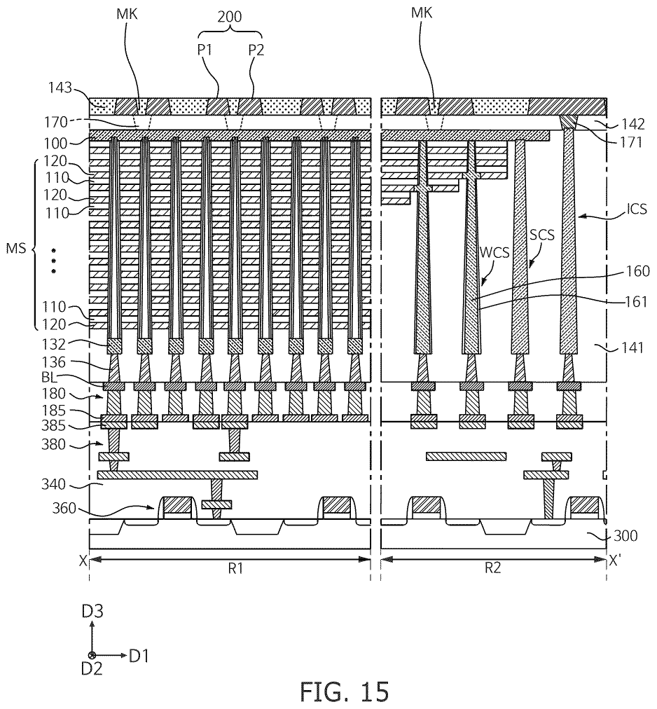

Referring to FIG. 15, the marker hole may be filled with the marker MK, and the space between the upper wires 200 may be filled with the third interlayer insulating film 143. The marker MK and the third interlayer insulating film 143 may be formed of the same or about the same insulating material. For example, the marker MK and the third interlayer insulating film 143 may contain at least one of silicon oxide, silicon nitride, and silicon carbide.

The process of forming the marker MK and the third interlayer insulating film 143 may be performed simultaneously (e.g., at or about at the same time). That is, after an insulating material has been injected into the marker hole and the space between the upper wires 200, the insulating material injected into the marker hole may be referred to as the marker MK, and the insulating material injected into the space between the upper wires 200 may be referred to as the third interlayer insulating film 143. In some example embodiments, the marker MK and the third interlayer insulating film 143 may be formed by separate processes. For example, the third interlayer insulating film 143 may be formed first, and then the marker MK may be formed, or vice versa. In some example embodiments, the marker MK may be formed of a metal different from the metal material forming the upper wire 200. For example, when the metal forming the upper wire 200 is aluminum (Al), the marker MK may be formed of tungsten (W).

A planarization process may be performed on the upper surfaces of the marker MK and the third interlayer insulating film 143. For example, the planarization process may be the chemical mechanical polishing (CMP) process.

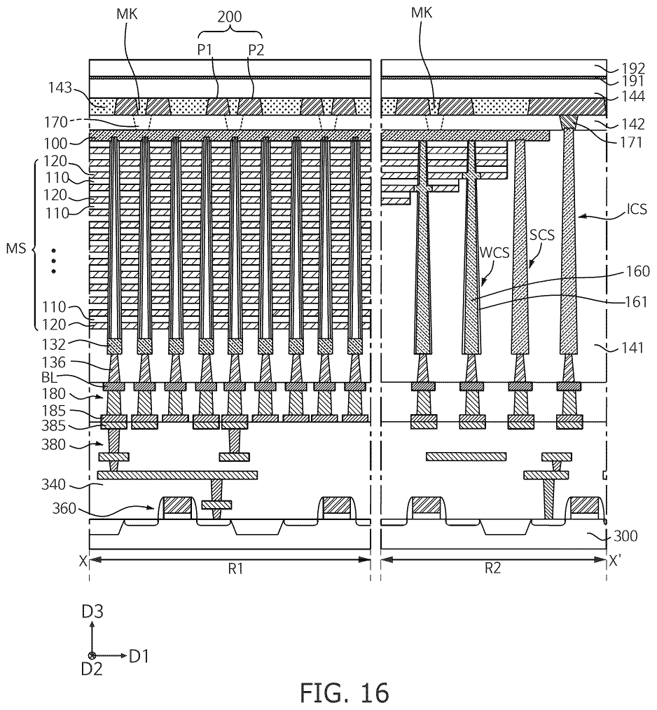

Referring to FIG. 16, the fourth interlayer insulating film 144 and the passivation layer 191 and 192 may be sequentially stacked on the upper surfaces of the marker MK and the third interlayer insulating film 143. The fourth interlayer insulating film 144 may be formed on the upper surfaces of the marker MK and the third interlayer insulating film 143, and the first passivation layer 191 and the second passivation layer 192 may be sequentially stacked thereon. The first passivation layer 191 may contain silicon nitride (SiN), and the second passivation layer 192 may contain a photosensitive insulating film. For example, the second passivation layer may contain a polyimide-based material such as photosensitive polyimide (PSPI).

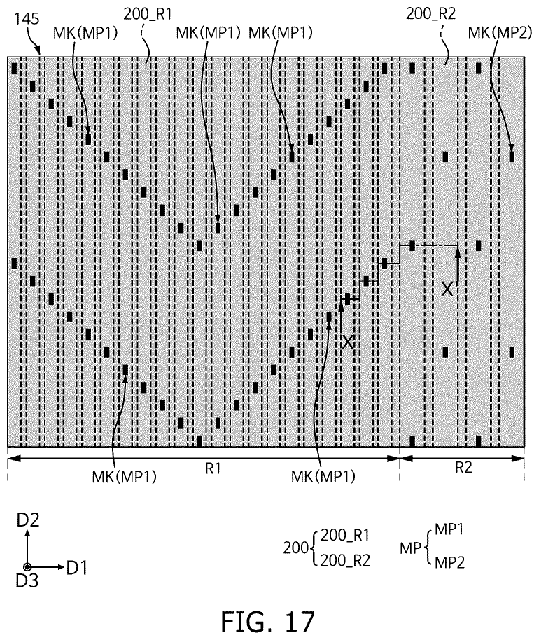

FIG. 17 is a plan view of a semiconductor device including a marker pattern according to some example embodiments of the present disclosure.

Referring to FIG. 17, the semiconductor device according to some example embodiments of the present disclosure may include the marker pattern MP arranged at a higher level than the upper wire 200. The marker pattern MP may include the plurality of markers MK. The marker pattern MP may overlap the upper wire 200 in a third direction D3. Each of the plurality of markers MK may overlap each of the plurality of upper wires 200 in the third direction D3.

The fourth interlayer insulating film 144 may be placed on the upper surfaces of the third interlayer insulating film 143 and the upper wire 200. A fifth interlayer insulating film 145 may be placed on the fourth interlayer insulating film 144.

The marker pattern MP may be arranged at the same or about the same level as the fifth interlayer insulating film 145. The marker pattern MP may overlap the fifth interlayer insulating film 145 in a first direction D1 and a second direction D2. The upper surface of the marker pattern MP may be positioned at the same or about the same level as the upper surface of the fifth interlayer insulating film 145. The upper surface of the marker MK may be coplanar or substantially coplanar with the upper surface of the fifth interlayer insulating film 145. The marker MK may penetrate the fifth interlayer insulating film 145 in the third direction D3. The lower surface of the marker MK may be in contact with the upper surface of the fourth interlayer insulating film 144.

The marker pattern MP may contain a metal material. For example, the marker pattern MP may contain tungsten (W), aluminum (Al), copper (Cu), tungsten nitride (WN), tantalum nitride (TaN), titanium nitride (TiN), or a combination thereof.

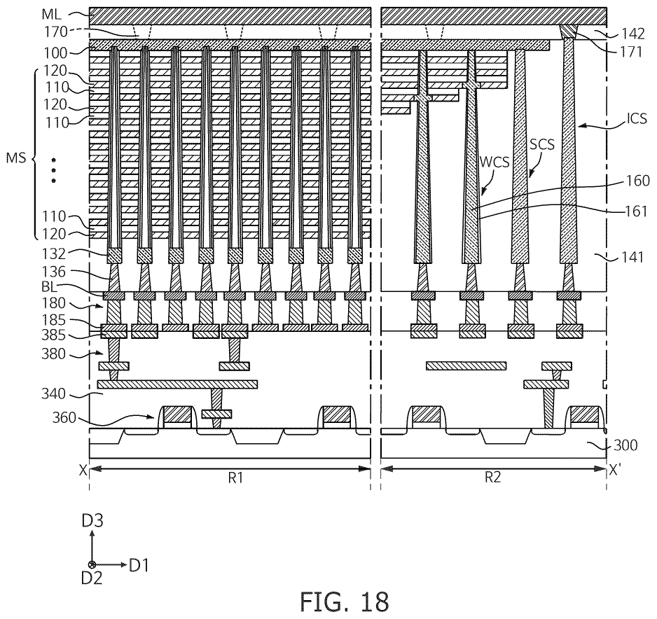

FIGS. 18 to 22 are views of intermediate steps of a method of manufacturing a semiconductor device according to some example embodiments of the present disclosure. FIGS. 18 to 22 are views corresponding to a cross section taken along line X-X′ in FIG. 17.

Referring to FIG. 18, the second interlayer insulating film 142 may be formed on the plate layer 100 and the first interlayer insulating film 141. The via hole may be formed in the second interlayer insulating film 142 through an etching process. A metal material may be injected onto the upper surfaces of the via hole and the second interlayer insulating film 142. Thereafter, a planarization process may be performed on the upper surfaces of the via structure 170 and 171 and the second interlayer insulating film 142. For example, the planarization process may be the chemical mechanical polishing (CMP) process.

The metal layer ML may be formed on the upper surfaces of the via structure 170 and 171 and the second interlayer insulating film 142. For example, the metal layer ML may contain tungsten (W), aluminum (Al), copper (Cu), tungsten nitride (WN), tantalum nitride (TaN), titanium nitride (TiN), or a combination thereof.

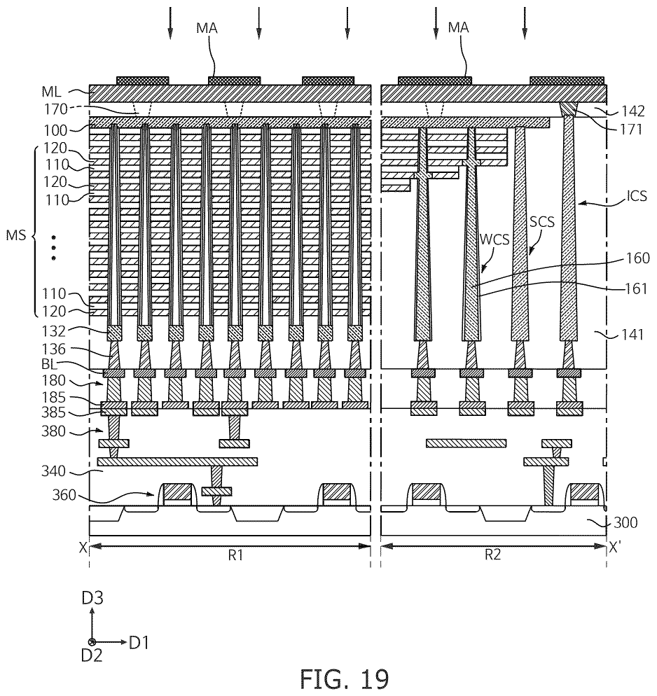

Referring to FIG. 19, the mask layer MA may be placed on the upper surface of the metal layer ML. An etching process may be carried out using the mask layer MA as an etching mask. A portion of the metal layer ML on which the mask layer MA is not disposed may be selectively removed through the etching process.

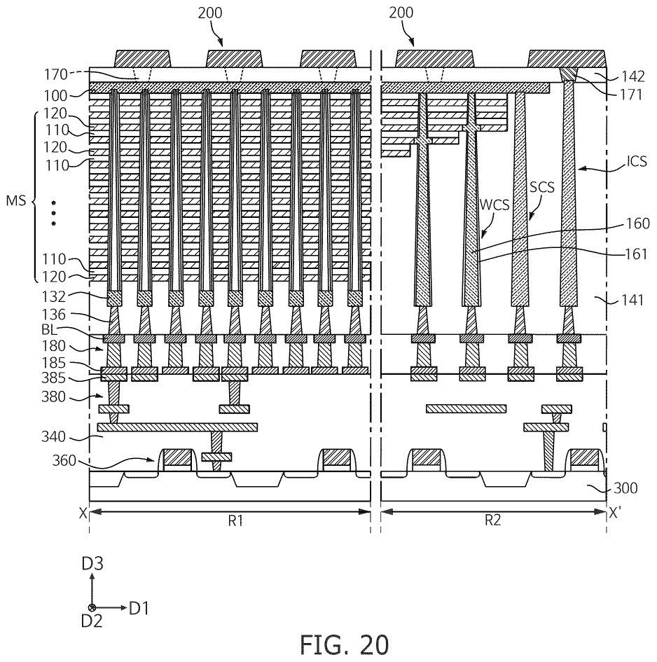

Referring to FIG. 20, the metal layer may be separated into the plurality of upper wires 200. The cross-sectional area of the upper wire 200 may increase toward the upper surface of the via structure 170 and 171. The width in a first direction D1 of the lower surface of the upper wire 200 may be greater than the width in the first direction D1 of the upper surface of the upper wire 200. A profile formed by an etching process may appear in the shape of the upper wire 200.

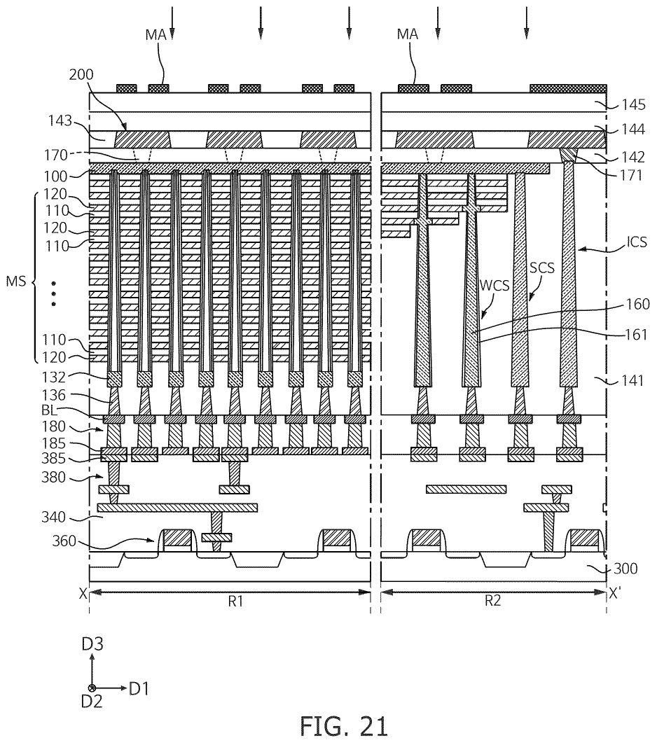

Referring to FIG. 21, the third interlayer insulating film 143 may be injected into the space between the upper wires 200. After an insulating material has been injected into the space between the upper wires 200, a planarization process may be performed on the upper surface of the third interlayer insulating film 143. For example, the planarization process may be the chemical mechanical polishing (CMP) process.

The fourth interlayer insulating film 144 and the fifth interlayer insulating film 145 may be sequentially formed on the upper surfaces of the upper wire 200 and the third interlayer insulating film 143. The fifth interlayer insulating film 145 may be formed on the fourth interlayer insulating film 144. The fourth interlayer insulating film 144 and the fifth interlayer insulating film 145 may be formed of the same or about the same insulating material, but the present disclosure is not limited thereto.

The mask layer MA may be placed on the upper surface of the fifth interlayer insulating film 145. An etching process can be performed using the mask layer MA as an etching mask. A portion of the fifth interlayer insulating film 145 on which the mask layer MA is not disposed may be selectively removed by the etching process. A marker hole may be formed by removing the portion of the fifth interlayer insulating film 145.

The cross-sectional area of the marker hole may become smaller toward the upper surface of the fourth interlayer insulating film 144. The width in a first direction D1 of the upper surface of the marker hole may be larger than the width in the first direction D1 of the lower surface of the marker hole. A profile formed by the etching process may appear in the shape of the marker hole.

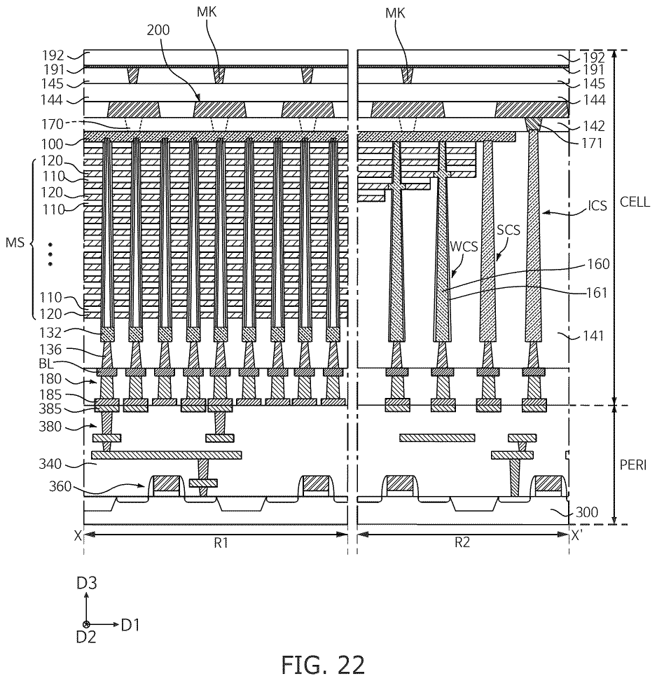

Referring to FIG. 22, a marker hole may be filled with a metal material to form the marker MK. The marker MK may be spaced apart from the upper wire 200 in a third direction D3. The marker MK may be electrically insulated from the upper wire 200.

The passivation layers 191 and 192 may be sequentially stacked on the upper surfaces of the marker MK and the fifth interlayer insulating film 145. The first passivation layer 191 and the second passivation layer 192 may be sequentially stacked on the upper surfaces of the marker MK and the fifth interlayer insulating film 145. The first passivation layer 191 may contain silicon nitride (SiN), and the second passivation layer 192 may contain a photosensitive insulating film. For example, the second passivation layer may contain a polyimide-based material such as photosensitive polyimide (PSPI).

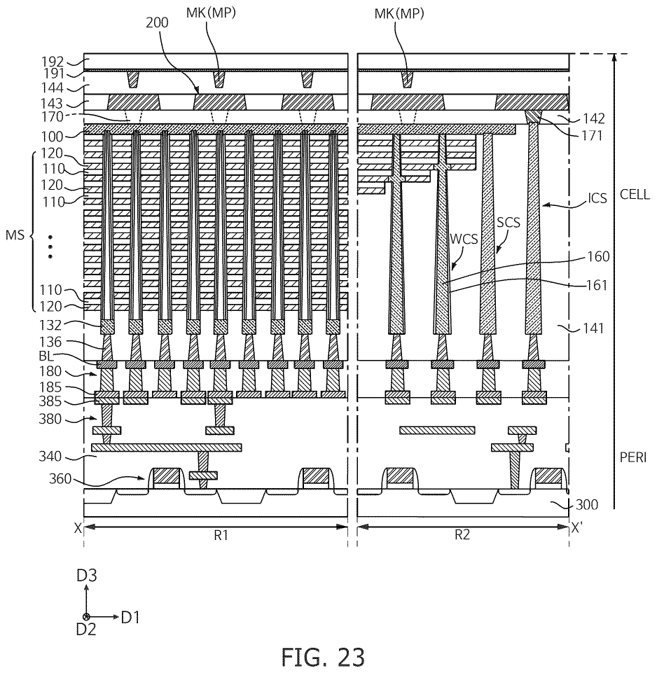

FIG. 23 is a plan view of a semiconductor device including a marker pattern according to some example embodiments of the present disclosure.

Referring to FIG. 23, the semiconductor device according to some example embodiments of the present disclosure may include the marker pattern MP disposed in the fourth interlayer insulating film 144. That is, the marker pattern MP may be formed in the fourth interlayer insulating film 144 placed on the upper surface of the upper wire 200.

The marker pattern MP may include the plurality of markers MK. The marker pattern MP may overlap the upper wire 200 in a third direction D3. Each of the plurality of markers MK may overlap each of the plurality of upper wires 200 in the third direction D3. The marker pattern MP may contain a metal material. For example, the marker pattern MP may contain tungsten (W), aluminum (Al), copper (Cu), tungsten nitride (WN), tantalum nitride (TaN), titanium nitride (TiN), or a combination thereof.

Each of the plurality of markers MK may overlap the fourth interlayer insulating film 144 in a first direction D1 and a second direction D2. The upper surface of the marker MK may be located at the same or about the same level as the upper surface of the fourth interlayer insulating film 144. The upper surface of the marker MK may be coplanar or substantially coplanar with the upper surface of the fourth interlayer insulating film 144.

The marker MK may penetrate a portion of the fourth interlayer insulating film 144 in a third direction D3. That is, even when an etching process is performed on the fourth interlayer insulating film 144, the upper surface of the upper wire 200 may not be exposed. The lower surface of the marker MK may be spaced apart from the upper surface of the upper wire 200 in the third direction D3. The marker MK and the upper wire 200 may be electrically insulated.

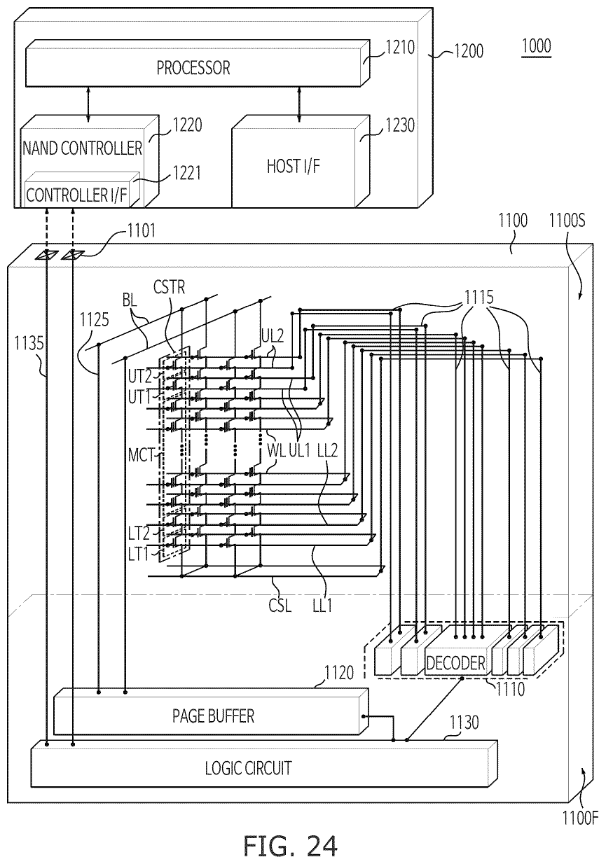

FIG. 24 is an example block diagram for illustrating an electronic system according to some example embodiments of the present disclosure.

Referring to FIG. 24, an electronic system 1000 according to some example embodiments of the present disclosure may include a semiconductor device 1100, which has been described with reference to FIGS. 1 to 11, 22, and 23, and a controller 1200 electrically connected to the semiconductor device 1100. The electronic system 1000 may be a storage device including one or more semiconductor devices 1100 or an electronic device including a storage device. For example, the electronic system 1000 may be a solid state drive (SSD) device, a universal serial bus (USB), a computing system, a medical device, or a communication device, including one or more semiconductor devices 1100.

For example, the semiconductor device 1100 may be a NAND flash memory device as described above with reference to FIGS. 1 to 11, 22, and 23. The semiconductor device 1100 may include a first structure 1100F and a second structure 1100S on the first structure 1100F. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

Each of the memory cell strings CSTR of the second structure 1100S may include lower transistors LT1 and LT2 adjacent to the common source line CSL, upper transistors UT1 and UT2 adjacent to the bit line BL, and a plurality of memory cell transistors MCT arranged between the lower transistors LT1 and LT2 and the upper transistors UT1 and UT2. The number of the lower transistors LT1 and LT2 and the number of the upper transistors UT1 and UT2 may vary depending on the embodiments.

In some example embodiments, the upper transistors UT1 and UT2 may include a string select transistor, and the lower transistors LT1 and LT2 may include a ground select transistor. The gate lower lines LL1 and LL2 may be gate electrodes of the lower transistors LT1 and LT2. The word lines WL may be gate electrodes of the memory cell transistors MCT, and the gate upper lines UL1 and UL2 may be gate electrodes of the upper transistors UT1 and UT2.

The common source line CSL, the first and second gate lower lines LL1 and LL2, the word lines WL, and the first and second gate upper lines UL1 and UL2 may be electrically connected to the decoder circuit 1110 through first connecting wires 1115 extending from within the first structure 1100F to the second structure 1100S. The bit lines BL may be electrically connected to the page buffer 1120 through second connecting wires 1125 extending from within the first structure 1100F to the second structure 1100S.

The decoder circuit 1110 and the page buffer 1120 of the first structure 1100F may control at least one of the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wiring 1135 extending from within the first structure 1100F to the second structure 1100S.

The controller 1200 may include a processor 1210, a NAND controller 1220, and a host interface 1230. In some example embodiments, the electronic system 1000 may include a plurality of semiconductor devices 1100, in which case the controller 1200 may control the plurality of semiconductor devices 1100.

The processor 1210 may control the overall operation of the electronic system 1000 including the controller 1200. The processor 1210 may operate based on a predetermined (or, alternatively, desired or selected) firmware and access the semiconductor device 1100 by controlling the NAND controller 1220. The NAND controller 1220 may include a NAND interface 1221 that handles communication with the semiconductor device 1100. Through the NAND interface 1221, a control command for controlling the semiconductor device 1100, data to be written to the memory cell transistors MCT of the semiconductor device 1100, data to be read from the memory cell transistors MCT of the semiconductor device 1100, etc. may be transmitted. Communication between the electronic system 1000 and an external host may be performed through the host interface 1230. When the processor 1210 receives a control command from an external host through the host interface 1230, it may control the semiconductor device 1100 in response to the control command.

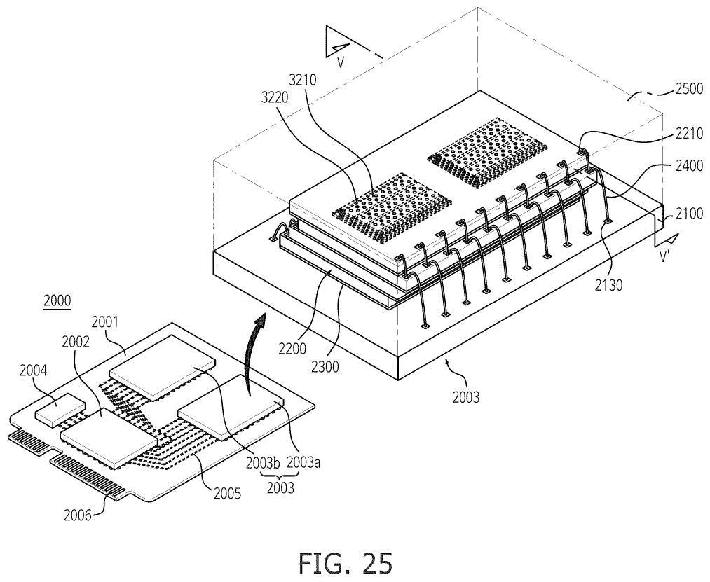

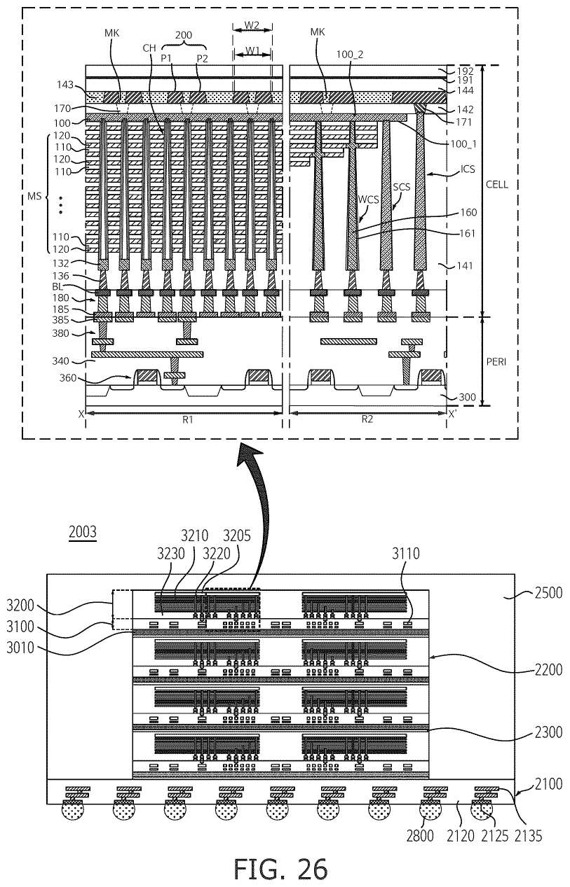

FIG. 25 is an example perspective view for illustrating an electronic system according to some example embodiments of the present disclosure. FIG. 26 is a schematic view of a cross section taken along line V-V in FIG. 24.

Referring to FIG. 25, an electronic system 2000 according to an embodiment of the present disclosure may include a main substrate 2001, a controller 2002 mounted on the main substrate 2001, one or more semiconductor packages 2003, and a DRAM 2004. The semiconductor package 2003 and the DRAM 2004 may be connected to the controller 2002 by wiring patterns 2005 formed on the main substrate 2001.

The main substrate 2001 may include a connector 2006 having a plurality of pins that are coupled with an external host. The number of the plurality of pins of the connector 2006 and how they are arranged may vary depending on the communication interface between the electronic system 2000 and the external host. In some example embodiments, the electronic system 2000 may communicate with an external host based on any one of the following interfaces: Universal Serial Bus (USB), Peripheral Component Interconnect Express (PCI-Express), Serial Advanced Technology Attachment (SATA), M-Phy for Universal Flash Storage (UFS), etc. In some example embodiments, the electronic system 2000 may be operated by power supplied from an external host through the connector 2006. The electronic system 2000 may further include a power management integrated circuit (PMIC) that distributes the power supplied from the external host to the controller 2002 and the semiconductor package 2003.

The main controller 2002 may write data to the semiconductor package 2003 or read data from the semiconductor package 2003, and may improve the operating speed of the electronic system 2000.

The DRAM 2004 may be a buffer memory to alleviate the speed difference between the semiconductor package 2003, which is space for data storage, and an external host. The DRAM 2004 of the electronic system 2000 may also serve as a type of cache memory and may provide space for temporarily storing data while controlling the semiconductor package 2003. When the electronic system 2000 includes the DRAM 2004, the main controller 2002 may further include a DRAM controller for controlling the DRAM 2004 in addition to a NAND controller for controlling the semiconductor package 2003.

The semiconductor package 2003 may include a first semiconductor package 2003a and a second semiconductor package 2003b that are spaced apart from each other. The first semiconductor package 2003a and the second semiconductor package 2003b may each be a semiconductor package including a plurality of semiconductor chips 2200. The first semiconductor package 2003a and the second semiconductor package 2003b may respectively include a package board 2100, the semiconductor chips 2200 on the package board 2100, adhesive layers 2300 arranged on the lower surface of each of the semiconductor chips 2200, a connecting structure 2400 electrically connecting the semiconductor chips 2200 and the package board 2100, and a molding layer 2500 covering the semiconductor chips 2200 and the connecting structure 2400 on the package board 2100.

The package board 2100 may be a printed circuit board including upper pads 2130. Each of the semiconductor chips 2200 may include an input/output pad 2210. The input/output pad 2210 may correspond to the input/output pad 1101 in FIG. 24. Each of the semiconductor chips 2200 may include metal lines 3210 and channel structures 3220. Each of the semiconductor chips 2200 may include the semiconductor device described above with reference to FIGS. 1 to 11, 22, and 23.

In some example embodiments, the connecting structure 2400 may be a bonding wire that electrically connects the input/output pad 2210 and the upper pads 2130. Accordingly, in each of the first semiconductor package 2003a and the second semiconductor package 2003b, the semiconductor chips 2200 may be electrically connected to each other by a bonding wire and may be electrically connected to the upper pads 2130 of the package board 2100. In some example embodiments, in each of the first semiconductor package 2003a and the second semiconductor package 2003b, the semiconductor chips 2200 may be electrically connected to each other by a connecting structure including a through silicon via (TSV) instead of the connecting structure 2400 in the form of a bonding wire.

In some example embodiments, the main controller 2002 and the semiconductor chips 2200 may be in a single package. In some example embodiments, the main controller 2002 and the semiconductor chips 2200 may be mounted on an interposer substrate other than the main substrate 2001, and the main controller 2002 and the semiconductor chips 2200 may be connected to each other by wiring formed on the interposer substrate.

In some example embodiments, the package board 2100 may be a printed circuit board. The package board 2100 may include a package board body 2120, the upper pads 2130 arranged on the upper surface of the package board body 2120, lower pads 2125 arranged on the lower surface of the package board body 2120 or exposed through the lower surface, and internal wirings 2135 electrically connecting the upper pads 2130 and the lower pads 2125 within the package board body 2120. The upper pads 2130 may be electrically connected to the connecting structures 2400. The lower pads 2125 may be connected to the wiring patterns 2005 of the main substrate 2001 of the electronic system 2000 through conductive connectors 2800 as illustrated in FIG. 25.

Each of the semiconductor chips 2200 of the semiconductor package 2003 may include a first structure 3100 on a semiconductor substrate 3010 and a second structure 3200 bonded to the first structure 3100 by wafer bonding on the first structure 3100.

The first structure 3100 may include a peripheral circuit area including peripheral wiring 3110 and first bonding structures.

The second structure 3200 may include a common source line 3205, a gate stacking structure 3210 between the common source line 3205 and the first structure 3100, the channel structures 3220 and a separation region 3230, which penetrate the gate stacking structure 3210, and second bonding structures each electrically connected to word lines of memory channel structures and the gate stacking structure 3210. The second structure 3200 may include the plate layer 100, the mold structure MS, the channel structure CH, the bit line BL, the contact structure WCS, etc., as shown in the enlarged view.

Each of the semiconductor chips 2200 of the electronic system according to some example embodiments may include the semiconductor device described above with reference to FIGS. 1 to 11, 22, and 23. For example, each of the semiconductor chips 2200 may include the peripheral circuit structure PERI and the cell structure CELL stacked on the peripheral circuit structure PERI. For example, the peripheral circuit structure PERI may include the peripheral circuit board 300 and the plurality of wiring structures 380 described above with reference to FIGS. 2, 22, and 23. In addition, for example, the cell structure CELL may include the plate layer 100, the mold structure MS, the channel structure CH, the bit line BL, the contact structure WCS, etc., described above with reference to FIGS. 1 to 11, 22, and 23. The peripheral circuit structure PERI and the cell structure CELL may be bonded to each other through a first bonding metal 185 and a second bonding metal 385.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Although the present disclosure has been described by means of some limited example embodiments and drawings, it is not limited thereto. It is needless to say that, by a person having ordinary skill in the technical field to which the present disclosure belongs, various modifications and variations can be made to the present disclosure within the scope of the technology of the present disclosure and the claims set forth below.

What is claimed is:

1. A semiconductor device comprising:
a peripheral circuit structure including a substrate having a first region and a second region and circuit elements on the substrate, the first region and the second region arranged in a first direction; and
a cell structure on the peripheral circuit structure,
the cell structure comprising
a mold structure including mold insulating layers and gate electrodes alternately stacked;
a channel structure penetrating the mold structure in the first region;
a contact structure in contact with the gate electrodes in the second region;
upper wires extending in a second direction intersecting the first direction; and
a marker pattern overlapping the upper wires in a third direction intersecting the first direction and the second direction.

2. The semiconductor device as claimed in claim 1, wherein the marker pattern overlaps the upper wires in the first direction and the second direction.

3. The semiconductor device as claimed in claim 2, wherein an upper surface of the marker pattern is at a same level as an upper surface of the upper wires.

4. The semiconductor device as claimed in claim 2, wherein a width in the first direction of an upper surface of the marker pattern is larger than a width in the first direction of a lower surface of the marker pattern.

5. The semiconductor device as claimed in claim 1, wherein
the upper wires comprise a first upper wire and a second upper wire spaced apart from the first upper wire in the first direction, and
the marker pattern comprises,
a first unit pattern comprising a first marker overlapping the first upper wire in the third direction and a second marker overlapping the second upper wire in the third direction, wherein the first marker and the second marker are positioned alternately in the first direction; and
a second unit pattern comprising a third marker overlapping the first marker in the first direction and a fourth marker overlapping the second marker in the first direction.

6. The semiconductor device as claimed in claim 5, wherein the first unit pattern and the second unit pattern are repeated in the first direction or the second direction.

7. The semiconductor device as claimed in claim 5, wherein the marker pattern further comprises an extension marker pattern overlapping at least a portion of the first unit pattern or the second unit pattern in the first direction and in the second region.

8. The semiconductor device as claimed in claim 7, wherein
the first unit pattern comprises a first reference marker at one end in the second direction and a second reference marker at another end, and
the extension marker pattern comprises,
a first extension marker overlapping the first reference marker in the first direction;
a second extension marker overlapping the second reference marker in the first direction; and
a third extension marker in a middle between the first extension marker and the second extension marker in the second direction.

9. The semiconductor device as claimed in claim 1, further comprising a plurality of word line cutting structures extending in the first direction in the first region and the second region and separating a plurality of cell blocks,
wherein at least a portion of the marker pattern overlaps the plurality of word line cutting structures in the third direction.

10. The semiconductor device as claimed in claim 5, wherein, in a plan view, the marker pattern comprises a zigzag pattern.

11. The semiconductor device as claimed in claim 1, further comprising an interlayer insulating film at a higher level than the upper wires,
wherein the marker pattern overlaps the interlayer insulating film in the first direction and the second direction.

12. The semiconductor device as claimed in claim 11, wherein the marker pattern comprises a metal material.

13. The semiconductor device as claimed in claim 1, wherein the peripheral circuit structure comprises a first bonding metal layer electrically connected to the channel structure, and the cell structure comprises a second bonding metal layer in contact with the first bonding metal layer.

14. The semiconductor device as claimed in claim 13, further comprising:
a plate layer comprising a first surface facing the peripheral circuit structure and a second surface opposite to the first surface and arranged on an upper surface of the mold structure; and
via structures spaced apart from each other in the first direction on the second surface of the plate layer,
wherein the upper wires are on an upper surface of the via structures.

15. A semiconductor device comprising:
a peripheral circuit structure including a substrate having a first region and a second region, and circuit elements on the substrate, the first region and the second region are in a first direction; and
a cell structure on the peripheral circuit structure,
wherein the cell structure comprises,
a mold structure including mold insulating layers and gate electrodes alternately stacked;
a channel structure penetrating the mold structure in the first region;
a contact structure in contact with the gate electrodes in the second region;
upper wires comprising a cell upper wire in the first region and an extension upper wire in the second region, extending in a second direction intersecting the first direction, and spaced apart from each other in the first direction; and
a marker pattern comprising a cell marker pattern overlapping the cell upper wire in a third direction intersecting the first direction and the second direction and an extension marker pattern overlapping the extension upper wire, and
the extension marker pattern overlaps at least a portion of the cell marker pattern in the first direction.

16. The semiconductor device as claimed in claim 15, wherein the marker pattern overlaps the upper wires in the first direction and the second direction and comprises an insulating material.

17. The semiconductor device as claimed in claim 16, wherein the cell marker pattern overlaps each of the upper wires adjacent to each other among the upper wires in the second direction.

18. The semiconductor device as claimed in claim 15, wherein each of a plurality of markers forming the marker pattern has a length in the second direction that is longer than a length in the first direction.

19. The semiconductor device as claimed in claim 15, wherein a length of the extension upper wire in the first direction is longer than a length of the cell upper wire in the first direction.

20. An electronic system comprising:
a main substrate;
a semiconductor device comprising a peripheral circuit structure and a cell structure stacked on the peripheral circuit structure on the main substrate; and
a controller electrically connected to the semiconductor device on the main substrate,
the cell structure comprising,
a mold structure including a plurality of mold insulating layers and a plurality of gate electrodes alternately stacked, the plurality of mold insulating layers and the plurality of gate electrodes extending in a first direction;
a channel structure penetrating the mold structure in a first region;
a contact structure contacting the plurality of gate electrodes in a second region;
upper wires comprising a cell upper wire in the first region and an extension upper wire in the second region, the upper wires extending in a second direction intersecting the first direction; and
a marker pattern comprising a cell marker pattern overlapping the cell upper wire in a third direction intersecting the first direction and the second direction, and an extension marker pattern overlapping the extension upper wire, and
the extension marker pattern overlaps at least a portion of the cell marker pattern in the first direction.
